(19) United States
(12) Patent Application Publication
(10) Pub. No.: US 2013/0003990 A1
(43) Pub. Date: Jan. 3, 2013

(54) ELECTRONIC DEVICE AND AUDIO OUTPUT CONTROL METHOD THEREOF

(75) Inventors: CHUNG-JEN WANG, Tu-Cheng (TW); LI-SHENG SHU, Shenzhen City (CN); TSUNG-JEN CHUANG, Tu-Cheng (TW); SHIH-FANG WONG, Tu-Cheng (TW)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/216,265

(22) Filed: Aug. 24, 2011

(30) Foreign Application Priority Data
Jun. 30, 2011 (CN) 201110181770.7

(51) Int. Cl. H03G 3/00

(52) U.S. Cl. 381/107

(57) ABSTRACT

An audio output port, an impedance value detecting unit, a DAC, an audio gain module, and a processing unit are included within an electronic device. The impedance value detecting unit detects the impedance value of an audio output apparatus. The storage unit stores an audio output mode table. The processing unit determines the range of impedance values that the detected impedance value falls within, and determines the corresponding audio output mode, the processing unit operates in the audio output mode which is required. The audio gain module magnifies the analog signals with a gain value corresponding to the audio output mode required, and transmits the magnified analog signals to the audio output port. An audio output control method is also provided.

### BACKGROUND

1. Technical Field

The present disclosure relates to an electronic device and an audio output control method thereof.

2. Description of Related Art

Usually, a user enjoys music on an electronic device via an audio output apparatus such as an earphone or a speaker. The electronic device generally defines a default audio output mode. For example, a media player may define its default audio output mode to be the earphone output. However, different audio output apparatuses such as different earphones may have different impedance values; for example, one may be 32 ohms (32Ω) and another may be 16Ω. Thus when the defined default audio output mode does not exactly match the audio output apparatus which is used, the sound output via the audio output apparatus can be seriously distorted.

Therefore, what is needed is an electronic device and an audio output control method thereof to alleviate the limitations described above.

### BRIEF DESCRIPTION OF THE DRAWINGS

The components in the drawings are not necessarily drawn to scale, the emphasis instead being placed upon clearly illustrating the principles of an electronic device and an audio output control method thereof. Moreover, in the drawings, like reference numerals designate corresponding sections throughout the several views.

FIG. 1 is a block diagram of an electronic device in accordance with an exemplary embodiment.

FIG. 2 is a table of audio output modes stored in the storage unit of the electronic device of FIG. 1, illustrating a number of impedance value ranges and corresponding audio output modes, in accordance with the exemplary embodiment.

FIG. 3 is a flowchart of an audio output control method for electronic devices, such as that of FIG. 1, in accordance with the exemplary embodiment.

### DETAILED DESCRIPTION

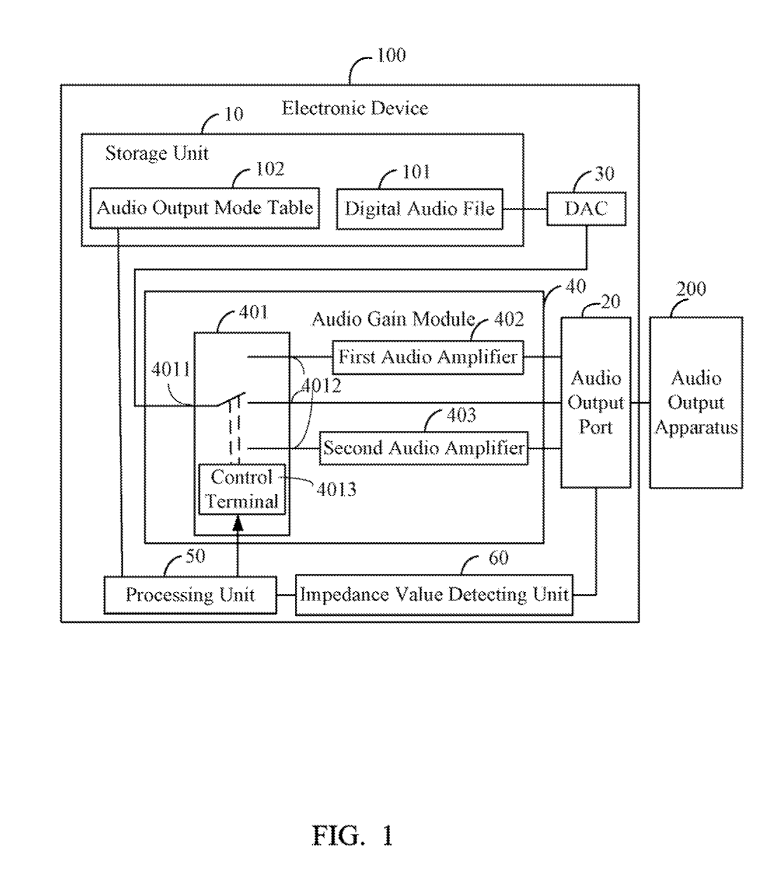

Referring to FIG. 1, an electronic device 100 is disclosed as part of an exemplary embodiment. The electronic device 100 includes a storage unit 10, an audio output port 20, a digital to analog converter (DAC) 30, an audio gain module 40, a processing unit 50, and an impedance value detecting unit 60. The electronic device 100 can be a mobile phone, a computer, an MP3, an electronic reader, or any other electronic device with an audio playing function.

The storage unit 10 stores at least one digital audio file 101 and an audio output mode table 102. The table 102 includes a number of impedance value ranges and audio output modes associated with the corresponding impedance value ranges.

The audio output port 20 is configured for connecting to an audio output apparatus 200. The audio output apparatus 200 may be chosen from a number of earphones and speakers with different power outputs.

Two terminals of the DAC 30 are connected to the digital audio file 101 and the audio gain module 40 respectively. The DAC 30 is configured for converting a digital audio file to analog audio signals. The audio gain module 40 is further connected to the audio output port 20.

Two terminals of the impedance value detecting unit 60 are connected to the audio output port 20 and the processing unit 50 respectively. The impedance value detecting unit 60 is configured for detecting the impedance value of the audio output apparatus 200, and transmitting the detected impedance value to the processing unit 50.

The processing unit 50 is configured for determining the impedance range within which the detected impedance value falls. The processing unit 50 is also configured for determining the audio output mode associated with the determined impedance value range within which the detected impedance value fell, according to the table 102, and controlling the electronic device 100 to operate in the determined audio output mode. In the embodiment, the audio gain module 40 provides different audio gain values to the analog audio signals based upon the audio output modes of the electronic device 100.

The audio gain module 40 is configured for responding to the control of the processing unit 50, to magnify the analog audio signals converted by the DAC 30 to an audio gain value which corresponds to the audio output mode of the electronic device 100, and to send the magnified analog audio signals to the audio output apparatus 200.

In the embodiment, the audio gain module 40 includes an electronic single-pole multi-throw switch 401, a first audio amplifier 402, and a second audio amplifier 403. The switch 401 includes a common terminal 4011 connected to the DAC 30, three fixing terminals 4012 fixedly connected to the first audio amplifier 402, the second audio amplifier 403, and the audio output port 20 respectively, and a control terminal 4013. The control terminal 4013 is connected to the processing unit 50 for receiving control signals from the processing unit 50. The common terminal 4011 can be alternatively connected to the first audio amplifier 402, or the second audio amplifier 403, or the audio output port 20. In the embodiment, the gain factor of the first audio amplifier 402 is small for an output apparatus such as earphones, but the gain factor of the second audio amplifier 403 is substantial for an output apparatus such as speakers.

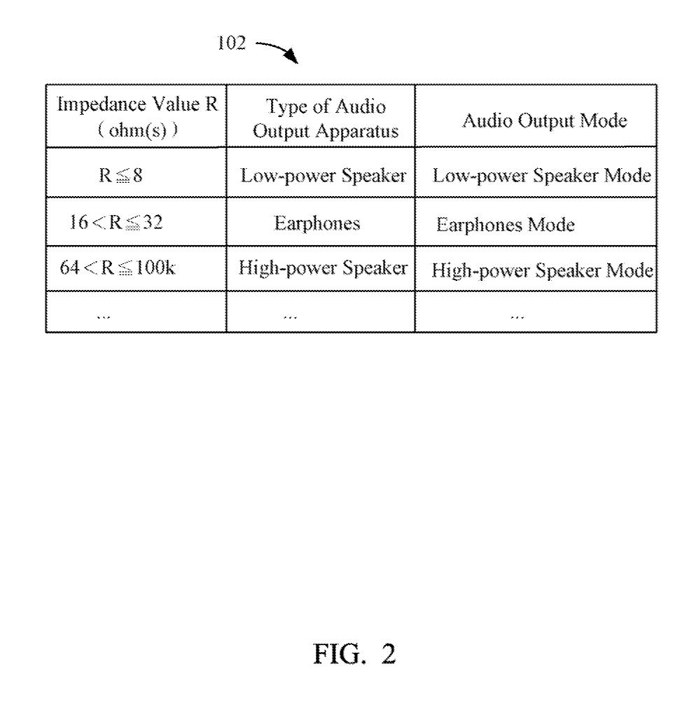

Referring to FIGS. 1 and 2, the table 102 includes data as to the impedance value ranges, the types of audio output apparatus, and the corresponding audio output modes. The table 102 includes three ranges of impedance values and three corresponding audio output modes. The audio output modes are a low-power speaker mode, an earphone mode, and a high-power speaker mode. The impedance values of low-power speakers are generally not more than 8 ohms, the impedance values of earphones are generally between 16 ohms and 32 ohms, and the impedance values of high-power speakers are generally between 64 ohms and 100K ohms. Thus, if the impedance value R of the audio output apparatus 200 is less than or equal to 8 ohms, the corresponding audio output mode is the low-power speaker mode; if the impedance value R of the audio output apparatus 200 is above 16 ohms to 32 ohms, the corresponding audio output mode is the earphone mode; if the impedance value R of the audio output apparatus is equal to or greater than 64 ohms, the corresponding audio output mode is the high-power speaker mode.

The processing unit 50 determines that the low-power speaker mode shall be operated if the impedance value R of the audio output apparatus 200 is less than or equal to 8 ohms, and controls the switch 401 to connect the DAC 30 with the second audio amplifier 403. The analog audio signals are amplified by the second audio amplifier 403 before being outputted to the audio output apparatus 200 via the audio output port 20.

The processing unit 50 determines that the earphone mode shall be operated if the impedance value R of the audio output apparatus is between 16 ohms and 32 ohms or equal to 32 ohms, and controls the switch 401 to connect the DAC 30 to the first audio amplifier 402. The analog audio signals are amplified by the first audio amplifier 402 before being outputted to the audio output apparatus 200 via the audio output port 20.

The processing unit 50 determines that the high-power speaker mode shall be operated if the impedance value R of the audio output apparatus is 64 ohms or more, and controls the switch 401 to connect the DAC 30 to the audio output port 20. In this case, the analog audio signals are output directly by the audio output port 20, without amplification.

In an alternative embodiment, the content and correlations within table 102 are defined according to actual needs. For example, the table 102 can include more than three ranges of impedance values and a corresponding number of audio output modes according to other examples of audio output apparatus 200 each with a different impedance value.

With such a configuration, the impedance value detecting unit 60 detects the impedance value of the audio output apparatus 200 when the audio output apparatus 200 is connected to the audio output port 20, and transmits the detected impedance value to the processing unit 50. The processing unit 50 determines the correct audio output to be operated according to the table 102, and controls the electronic device 100 to output the appropriate analog audio signals via the audio output port 20. Thus the matching of the analog audio signals to the audio output apparatus 200 produces a truer and higher quality sound.

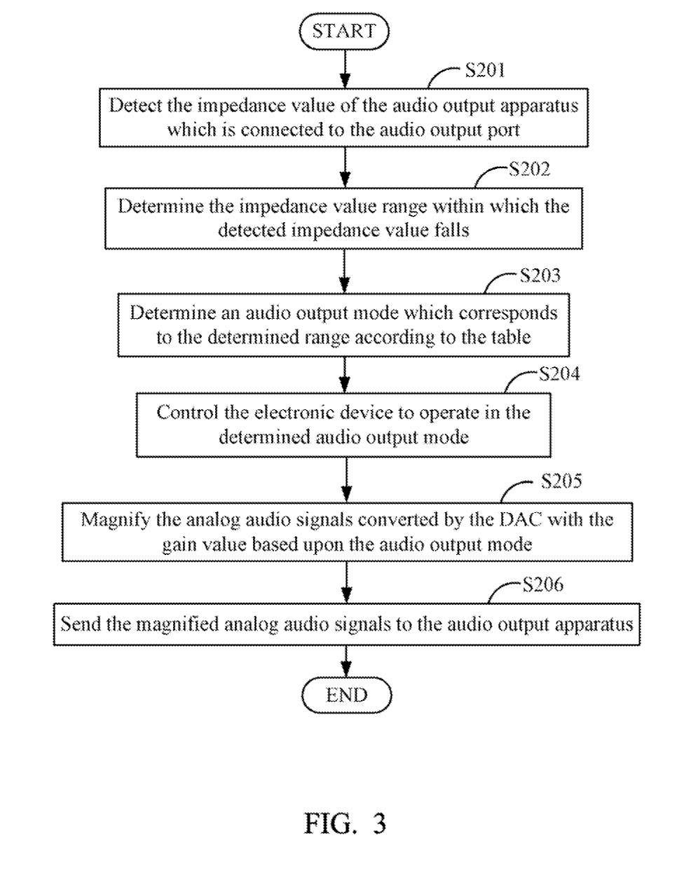

Referring to FIG. 3, a flowchart of an audio output control method is shown. The method includes the following steps, each of which is connected to various components contained in the electronic device 100 shown in FIG. 1.

In step S201, the impedance value detecting unit 60 detects the impedance value of the audio output apparatus 200 which is connected to the audio output port 20.

In step S202, the processing unit 50 determines impedance value range within which the detected impedance value falls.

In step S203, the processing unit 50 determines an audio output mode which corresponds to the determined range according to the table 102.

In step S204, the processing unit 50 controls the electronic device 100 to operate in the determined audio output mode.

In step S205, the audio gain module 40 magnifies the analog audio signals converted by the DAC 30 with the gain value based on the audio output mode.

In step S206, the audio gain module 40 sends the magnified analog audio signals to the audio output apparatus 200.

Although the present disclosure has been specifically described on the basis of the embodiments thereof, the disclosure is not to be construed as being limited thereto. Various changes or modifications may be made to the embodiments without departing from the scope and spirit of the disclosure.

What is claimed is:

1. An electronic device, comprising:
an audio output port configured to connect to an audio output apparatus;
an impedance value detecting unit, configured to detect an impedance value of the audio output apparatus;
a storage unit storing a digital audio file and an audio output mode table, the audio output mode table comprising a plurality of impedance value ranges and a plurality of audio output modes associated with the corresponding impedance value ranges;
a DAC configured to convert the digital audio file to analog audio signals;
a processing unit configured to determine the impedance value range within which the detected impedance value transmitted from the impedance value detecting unit falls, determine an audio output mode associated with the determined impedance value range according to the audio output mode table, and control the electronic device to operate in the determined audio output mode; and
an audio gain module connected between the DAC and the audio output port, the audio gain module configured for providing different audio gain values to the analog audio signals based upon the audio output modes of the electronic device, the audio gain module also configured to magnify the analog audio signals converted by the DAC to an audio gain value which corresponds to the audio output mode of the electronic device, and to send the magnified analog audio signals to the audio output apparatus.

2. The electronic device as described in claim 1, wherein the audio output modes are selected from the group consist of: an earphones mode, a high-power speaker mode, and a low-power speaker mode, and the audio output mode table comprises a first impedance value range corresponding to the low-power speaker mode, a second impedance value range corresponding to the earphones mode, and a third impedance value range corresponding to the high-power speaker mode.

3. The electronic device as described in claim 2, wherein the processing unit is configured to determine the low-power speaker mode for the electronic device according to the audio output mode table if the impedance value of the audio output apparatus falls in the first impedance value range, the processing unit is configured to determine the earphones mode for the electronic device according to the audio output mode table if the impedance value of the audio output apparatus falls in the second impedance value range, and the processing unit is configured to determine the high-power speaker mode for the electronic device according to the audio output mode table if the impedance value of the audio output apparatus falls in the third impedance value range.

4. The electronic device as described in claim 3, wherein the first impedance value range is less than or equal to 8 ohms.

5. The electronic device as described in claim 3, wherein the second impedance value range is from above 16 ohms to 32 ohms.

6. The electronic device as described in claim 3, wherein the third impedance value range is equal to or greater than 64 ohms.

7. The electronic device as described in claim 1, wherein the audio gain module comprises a first audio amplifier, a second audio amplifier, and an electronic single-pole multi-throw switch, the electronic single-pole multi-throw switch is connected to the DAC and is selectively connectable to the first audio amplifier, the second audio amplifier, and the audio output port.

8. The electronic device as described in claim 7, wherein when the electronic device operates in the low-power speaker mode, the processing unit is configured to control the electronic single-pole multi-throw switch to connect the DAC to the second audio amplifier, and the second audio amplifier is configured to amplify the analog audio signals for outputting; when the electronic device operates in the earphones mode, the processing unit is configured to control the electronic single-pole multi-throw switch to connect the DAC to the first audio amplifier, and the first audio amplifier is configured to amplify the analog audio signals for outputting; when the electronic device operates in the high-power speaker mode, the processing unit is configured to control the electronic single-pole multi-throw switch to connect the DAC to the audio output port, and the audio output port is configured to output the analog audio signals.

9. The electronic device as described in claim 1, being a mobile phone.

10. An audio output control method for an electronic device, the electronic device comprising a storage unit, a DAC, an audio gain module, and an audio output port, the storage unit storing a digital audio file and an audio output mode table, the audio output mode table comprising a plurality of impedance value ranges and a plurality of audio output modes respectively associated with the corresponding impedance value ranges, the audio gain module configured to provide different gain values based on the audio output modes of the electronic device, the DAC being configured to convert the digital audio file to analog audio signals, the audio output port being connected to an audio output apparatus, the method comprising:
detecting an impedance value of the audio output apparatus which is connected to the audio output port;
determining the impedance value range within which the detected impedance value falls;
determining an audio output mode which corresponds to the determined impedance value range according to the audio output mode table;
controlling the electronic device to operate in the determined audio output mode;
magnifying the analog audio signals converted by the DAC with the gain value based upon the audio output mode; and
sending the magnified analog audio signals to the audio output apparatus.
